(19) United States
(12) Patent Application Publication
(10) Pub. No.: US 2026/0354242 A1
(43) Pub. Date: Nov. 5, 2026

(54) WAFER BONDING STRUCTURE AND WAFER BONDING METHOD THEREOF

(71) Applicant: UNITED MICROELECTRONICS CORP., Hsin-Chu City (TW)

(72) Inventors: Chau-Chung Hou, Tainan City (TW); Ang Chan, Taipei City (TW); Chi-Wen Chen, Kaohsiung City (TW); Hsin-Jung Liu, Pingtung County (TW)

(73) Assignee: UNITED MICROELECTRONICS CORP., Hsin-Chu City (TW)

(21) Appl. No.: 19/207,421

(22) Filed: May 14, 2025

(30) Foreign Application Priority Data
Apr. 30, 2025 (TW) 114116354

(51) Int. Cl. H10W 72/00; H10W 80/00; H10W 90/00

(52) U.S. Cl. CPC H10W 72/00; H10W 80/312; H10W 80/327; H10W 90/792

(57) ABSTRACT

The present invention discloses a wafer bonding structure, which includes a first wafer having a first front surface and a first back surface, and a second wafer having a second front surface and a second back surface, wherein the second front surface of the second wafer is bonded to the first front surface of the first wafer. The first wafer and the second wafer also have an outermost edge region, where the edge region of the first wafer is not bonded to the edge region of the second wafer. Additionally, there is a first through-silicon via (TSV) in the edge region of the first wafer exposed from the back surface of the first wafer.

### BACKGROUND OF THE INVENTION

### 1. Field of the Invention

The present invention generally relates to a wafer bonding structure, and more specifically, to a wafer bonding structure incorporating through-silicon vias (TSVs) in the edge region of a wafer, as well as a method for wafer bonding.

### 3. Description of the Prior Art

With the continuous advancement of integrated circuit (IC) technology, transistor density has steadily increased, while critical dimensions have continued to shrink. As a result, defects generated during the photolithography process are having a more pronounced impact on device yield and quality. Among the key control factors in photolithography, wafer edge cleanliness and definition have become increasingly critical. During the photolithography process, photoresist is typically applied to the wafer surface using a spin-coating process. However, due to the centrifugal forces involved in spin coating, photoresist material can inevitably splash onto undesired areas, such as the wafer edge or even the wafer backside. This results in photoresist accumulation on both the top and bottom surfaces near the wafer edge. Such accumulations may come into mechanical contact with wafer handling equipment during subsequent etching or ion implantation processes, potentially causing particle contamination, degraded wafer handling precision, or even detachment of photoresist residues during high-temperature processes. These issues can lead to contamination of the process chamber, resulting in equipment downtime, elevated maintenance costs, and significant production delays.

To mitigate these issues, photoresist edge bead removal (EBR) is typically performed on the wafer surface during the photolithography process. Currently, mainstream photoresist edge removal techniques fall into two primary categories: Edge Bead Removal (EBR) and Wafer Edge Exposure (WEE). Specifically, EBR involves spraying a solvent onto the wafer edge during the spin-coating process to dissolve and eliminate the bead-like accumulations of photoresist. WEE, on the other hand, is carried out after the photoresist has been applied but prior to exposure. This method utilizes an additional photomask to selectively expose the wafer edge, enabling the unwanted edge photoresist to be removed during the subsequent development step.

However, while the aforementioned photoresist edge removal processes effectively mitigate contamination at the wafer edge, they can also cause layer structure degradation in regions near the wafer edge due to the removal of photoresist. As illustrated in FIG. 1, which shows a cross-sectional view of a conventional wafer following photoresist edge removal, different regions of the wafer and their corresponding layer structures - such as the front-end device layers and back-end metal interconnect layers - are depicted. It should be noted that in FIG. 1, the farther to the right a region appears, the closer it is to the actual wafer edge, with the rightmost area representing the edge itself. From this figure, it is clear that the severity of layer structure loss increases as one moves closer to the wafer edge. Issues such as metal layer delamination (as indicated by reference numeral 10) and/or removal of inter-metal dielectric (IMD) layers (as indicated by reference numeral 12) are apparent. These defects result in substantial structural discrepancies between the peripheral regions of the wafer and the more stable central areas.

While such structural losses near the wafer edge generally do not pose significant issues in standard wafer processing—since edge dies or peripheral regions are typically discarded during the dicing process—they can lead to serious complications in wafer-on-wafer (WoW) bonding technology. As shown in FIG. 2, which presents a cross-sectional view of a wafer bonding structure formed from wafers that have undergone photoresist edge removal, two wafers (W1 and W2) are bonded with their front sides (i.e., the sides containing device layers and metal interconnects) facing each other. FIG. 2 reveals that due to the structural degradation caused by photoresist edge removal, an unbonded region 14 appears near the edges of the bonded wafers. This region lacks the conventional inter-metal dielectric (IMD) layers and/or metal layers necessary to form a robust bonding interface (BI), resulting in the formation of a gap 16. As a result, this area lacks sufficient mechanical support, making it particularly vulnerable to edge chipping during subsequent processing steps such as backside grinding or edge trimming. This mechanical fragility can severely impact process yield and device reliability. Furthermore, as the number of wafers stacked in the bonding structure increases, the extent of the unbonded edge region 14 also expands, thereby amplifying the risk of wafer edge damage. Therefore, there is a critical need for those of skilled in the art to improve wafer bonding structure designs to effectively mitigate these issues, enhance process stability, and ensure high final product quality.

### SUMMARY OF THE INVENTION

In view of the shortcomings of the conventional technologies described above, the present invention hereby proposes a novel wafer bonding structure and an associated wafer bonding method. A distinguishing feature of this invention is the integration of through-silicon vias (TSVs) in the edge region of the wafer bonding structure. These TSVs provide enhanced mechanical reinforcement to the wafer edge, effectively mitigating the risk of edge chipping during subsequent manufacturing steps such as backside grinding and edge trimming. Consequently, the proposed structure significantly improves process yield and overall reliability.

One aspect of the present invention is to provide a wafer bonding structure, including: a first wafer having a first front side and a first back side; a second wafer having a second front side and a second back side, wherein the second front side of the second wafer is bonded to the first front side of the first wafer, and the first wafer and the second wafer have an outermost edge region, and the edge region of the first wafer is not bonded to the edge region of the second wafer; and a first TSV located in the edge region of the first wafer and extending through the first wafer to expose at the first back side of the first wafer.

Another aspect of the present invention is to provide a wafer bonding method, including: providing a first wafer and a second wafer, wherein the first wafer has a first front side and a first back side, and the second wafer has a second front side and a second back side, and the first wafer and the second wafer have an outermost edge region, a first TSV located in the edge region of the first wafer and extending through the first wafer to expose at the first back side of the first wafer; directly bonding the first front side of the first wafer to the second front side of the second wafer, wherein the edge region of the first wafer is not bonded to the edge region of the second wafer; and performing a backside thinning process to remove a portion of the first wafer and a portion of the first TSVs from the first back side of the first wafer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a schematic cross-sectional view of a wafer that has undergone photoresist edge removal treatment in conventional skill;

FIG. 2 is a schematic cross-sectional view of a wafer bonding structure formed by bonding wafers that have undergone photoresist edge removal treatment, according to conventional skill;

FIG. 3 is a schematic cross-sectional view of a wafer bonding structure in accordance with a preferred embodiment of the present invention;

FIG. 4 is a schematic cross-sectional view of a wafer bonding structure after backside grinding and edge trimming in accordance with a preferred embodiment of the present invention;

FIG. 5 is a schematic top view and a partial enlarged view of a wafer bonding structure in accordance with one embodiment of the present invention; and

FIG. 6 is a flowchart illustrating the steps of a wafer bonding method in accordance with a preferred embodiment of the present invention.

Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description of the present invention, reference is made to the accompanying drawings which form a part hereof and is shown by way of illustration and specific embodiments in which the invention may be practiced. These embodiments are described in sufficient details to enable those skilled in the art to practice the invention. Other embodiments may be utilized and structural, logical, and electrical changes may be made without departing from the scope of the present invention. The following detailed description, therefore, is not to be taken in a limiting sense, and the scope of the present invention is defined by the appended claims.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). In addition, spatially relative terms, such as “beneath,” “below,” “lower,” “above,” “upper,” and the like, may be used herein for ease of description to describe one element or feature’s relationship to another element(s) or feature(s) as illustrated in the figures.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon (Si), germanium (Ge), gallium arsenide (GaAs), indium phosphide (InP), etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term "based on" may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

The following detailed description of the present invention is provided with reference to the accompanying drawings, which form an integral part of this disclosure and illustrate specific embodiments in a manner that facilitates implementation. These embodiments are described in sufficient detail to enable those skilled in the art to practice the invention. For clarity and ease of understanding, certain dimensions and proportions in the drawings may be deliberately minimized or exaggerated. It should be appreciated that various other embodiments and modifications - whether structural, logical, or electrical - may be employed without departing from the spirit and scope of the invention. Accordingly, the following description is intended for illustrative purposes only and should not be considered limiting, with the scope of the invention being defined solely by the appended claims.

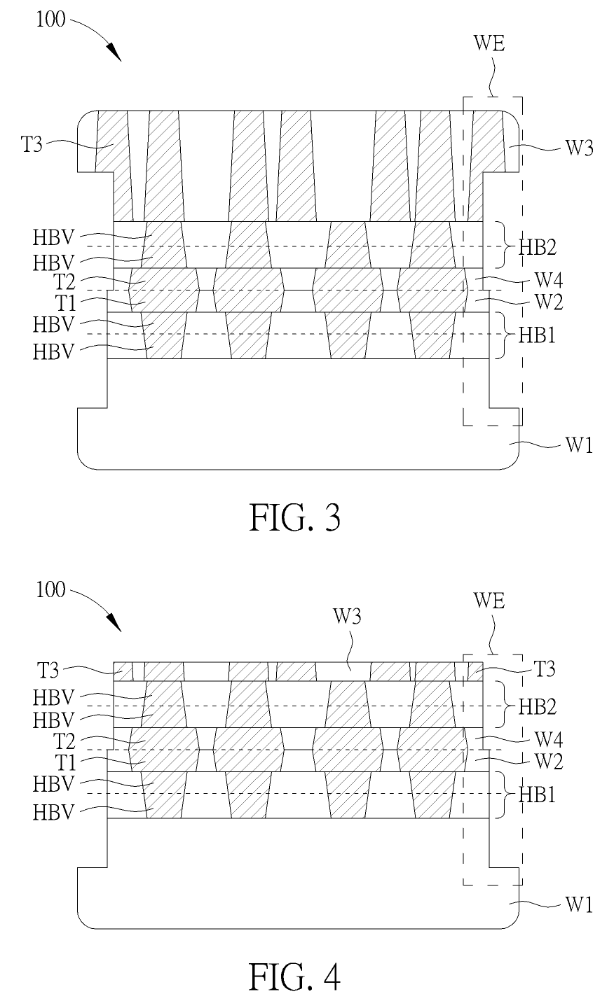

Please refer first to FIG. 3, which illustrates a schematic cross-sectional view of a wafer bonding structure 100 in accordance with a preferred embodiment of the present invention. In this embodiment, the wafer bonding structure 100 comprises a plurality of wafers, specifically wafers W1 to W4 (collectively referred to as functional wafers), which are bonded together to form a 3D IC structure. These wafers W1–W4 may be stacked using hybrid bonding technology to achieve wafer-on-wafer (WoW) system integration at wafer-level. This advanced bonding technique significantly increases both the density and number of interconnects within the 3D IC, while eliminating the need for conventional physical contacts. As a result, it effectively shortens interconnect lengths, thereby reducing overall system power consumption and required layout area. Moreover, it enhances data transmission bandwidth between logic circuits and memory, thereby successfully overcoming the high bandwidth memory (HBM) bottleneck commonly encountered in high-performance computing applications, such as those involving artificial intelligence (AI). Ultimately, this leads to improved computational performance of the overall chip system. It is noted that each of the wafers W1–W4 in FIG. 3 includes a device layer—formed during the front-end-of-line (FEOL) process, comprising logic circuits or memory cells—and one or more metal interconnect layers, which are formed during the back-end-of-line (BEOL) process and contain metal wirings and hybrid bonding bumps. For clarity, detailed components within these layers are omitted in the figure. Additionally, while this embodiment illustrates a four-wafer stack, the number of wafers in the wafer bonding structure is not limited to this example.

In the embodiment illustrated in FIG. 3, wafers W1 and W2 constitute a first wafer pair, which are electrically and mechanically bonded through corresponding hybrid bonding vias (HBVs) within a hybrid bonding layer HB1. In this embodiment, hybrid bonding layer HB1 represents the topmost layer of the BEOL metal interconnects of wafers W1 and W2. These wafers may, for example, incorporate CPU logic circuits and DRAM memory circuits, or may comprise advanced high-performance AI computing chips. Notably, wafer W1 has not undergone backside grinding and therefore retains a relatively thick semiconductor substrate. This unthinned substrate serves as a mechanical support base during the processing of the overall wafer bonding structure 100. In contrast, wafer W2 has been thinned by backside grinding, reducing its original substrate thickness down to approximately the level of the device layer. This thinning process reduces the overall thickness of the wafer bonding structure, facilitates the vertical stacking of additional functional wafers within the wafer bonding structure 100. Furthermore, wafer W2 includes a through-silicon via (TSV) T1, which extends vertically through the entire wafer W2. One end of TSV T1 is electrically connected to the hybrid bonding via (HBV) located within hybrid bonding layer HB1. Similarly, wafers W3 and W4 constitute a second wafer pair, also bonded together through hybrid bonding vias HBV in a hybrid bonding layer HB2, This configuration likewise provides both electrical and mechanical interconnection. In this embodiment, hybrid bonding layer HB2 is likewise the topmost layer of the BEOL metal interconnects of wafers W3 and W4. These wafers may similarly include CPU logic and DRAM memory circuits, or high-performance AI chips. Notably, wafer W3, like wafer W1, has not yet undergone backside grinding and therefore retains its thicker semiconductor substrate, which is intended to be thinned in a subsequent grinding process. Wafer W4, on the other hand, has already been thinned down to the device layer through backside grinding. This contributes to reducing the overall thickness of the bonding structure and further supports the stacking of additional functional wafers in the wafer bonding structure 100. Furthermore, wafer W4 includes a TSV T2, which extends vertically through the entire wafer W4, with one end connected to the corresponding hybrid bonding via HBV within hybrid bonding layer HB2.

Referring again to FIG. 3, the aforementioned first and second wafer pair can be electrically connected through the TSVs T1 and T2, which are respectively formed in wafers W2 and W4. For instance, wafers W2 and W4 may both be memory wafers incorporating high-bandwidth memory (HBM), wherein the memory circuits are interconnected via TSVs T1 and T2. This configuration not only increases overall memory capacity but also enables high-speed data transmission between memory layers. Furthermore, in this embodiment of the invention, wafer W3 - which has not yet undergone backside grinding and therefore retains a thick substrate - includes a TSV T3 that extends vertically through the entire wafer W3. One end of TSV T3 is exposed at the backside of wafer W3, while the opposite end is electrically connected to the hybrid bonding via HBV in the hybrid bonding layer HB2. In a preferred embodiment, wafer W3 serves as the topmost wafer in the wafer bonding structure 100. After packaging, the exposed TSV T3 can be electrically connected to a flip-chip bump or package bump (not shown), thereby enabling the entire wafer bonding structure 100 to interface with external circuitry, such as a PCB. TSV T3 may be fabricated using a via-middle process. Compared to other TSV formation techniques, via-middle TSVs are better suited to satisfy the three critical design requirements of high frequency performance, low power consumption, and dimension scalability. These characteristics make via-middle TSVs ideal for the high-performance computing demands of modern AI chips. Further details of this implementation are described in the method embodiments provided in the subsequent sections.

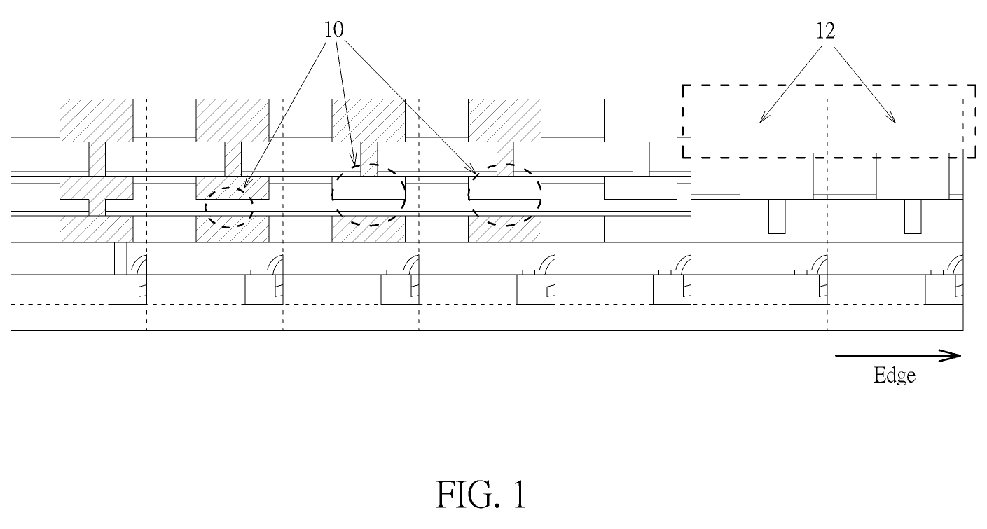

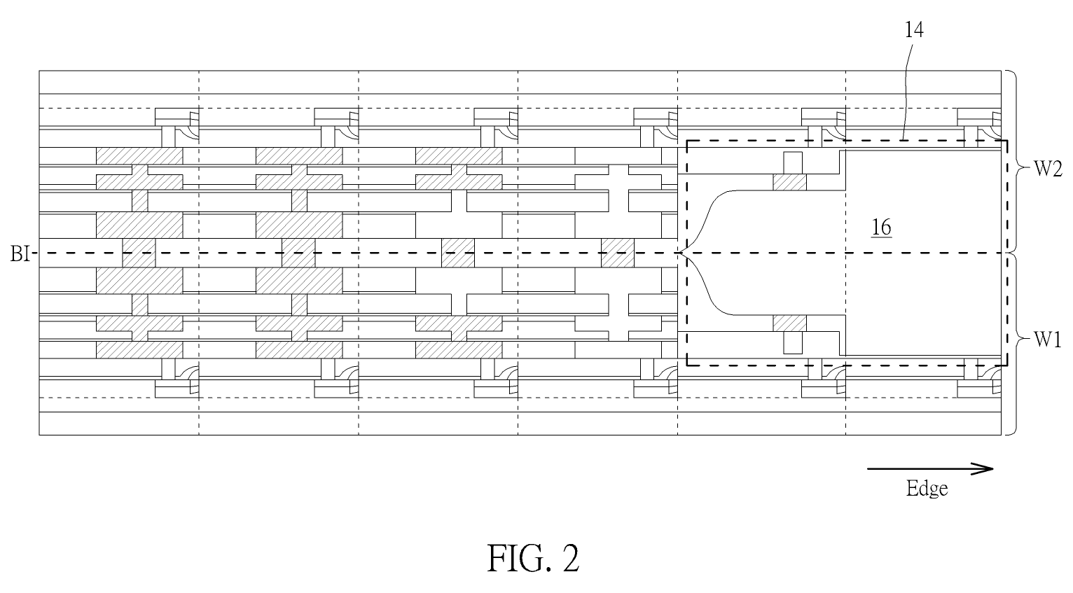

Referring again to FIG. 3, in this embodiment, the wafer bonding structure 100 includes an outer edge region WE, located along the outermost perimeter of the wafers. As previously described in prior art section, the edge region WE refers to an unbonded area of the wafer, which is typically excluded and discarded after dicing of the wafer bonding structure 100. In certain embodiments, the edge region WE corresponds to what is commonly referred to as the wafer bevel, which may feature a rounded profile or sloped surface. Structurally, the edge region WE is characterized by the loss of layer integrity due to the photoresist edge removal process (as shown in FIG. 1). This degradation prevents the formation of a proper wafer bonding interface (as depicted in FIG. 2), thereby resulting in insufficient mechanical support in this area. Specifically, for wafers W1 through W4, the hybrid bonding layers HB1 and HB2 located within the edge region WE do not contain hybrid bonding vias HBVs , as indicated by reference numeral 10 in FIG. 1. Alternatively, in the edge region WE of wafers W1 to W4, the hybrid bonding layers HB1 and HB2 are separated by a physical gap (see gap 16 in FIG. 2), thereby failing to establish electrical interconnection between the wafers. These structural deficiencies in the edge region WE significantly increase the risk of edge chipping during subsequent manufacturing processes, such as backside grinding or edge trimming, which may negatively impact overall process yield and device reliability. This risk is further exacerbated when the wafer bonding structure comprises a larger number of stacked wafers, further amplifying the risk of wafer edge damage.

In contrast to conventional technologies, a notable feature of the present invention is that the TSV T3 - used for connecting the wafer bonding structure to external circuitry - is also formed within the edge region WE of the wafer. Please refer to FIG. 5, which provides a schematic top view and a partially enlarged view of a wafer bonding structure 100 according to one embodiment of the invention. As illustrated, the wafer bonding structure 100 includes an edge region WE, located along the outermost perimeter of the wafer, and a main region WC, which is surrounded by the edge region WE. As previously described, in wafer stacking technologies, the edge region WE is considered an unbonded area and is typically excluded and discarded after the dicing process. The main region WC corresponds to the regular, functional area of the wafer, which is diced into multiple individual dies with complete structural integrity. In conventional designs, no TSVs - such as the TSV T3 used for connecting functional layers to external circuits - are formed in the edge region WE, as it is not considered part of the usable chip area. However, in the wafer bonding structure 100 of the present invention, as shown in FIG. 5, TSVs T3 are formed not only in the main region WC, but also formed within the unbonded edge region WE. These TSVs T3, which are made of conductive materials such as copper (Cu) or tungsten (W), provide added mechanical reinforcement to the structurally weakened edge region WE. This reinforcement helps mitigate the risk of edge chipping during subsequent processing steps such as backside grinding and edge trimming, thereby significantly improving the mechanical robustness and reliability of the wafer bonding structure - representing a key advantage of the invention. In one embodiment, the edge region WE may have a width of approximately 2 mm, and each TSV T3 may have a hole diameter of around 6 μm. The TSVs T3 may be distributed within a zone extending approximately 1 mm outward from the inner boundary of the edge region WE, thereby ensuring sufficient structural support around the wafer’s periphery.

Now, please refer to FIG. 4, which illustrates a schematic cross-sectional view of the wafer bonding structure 100 after undergoing backside grinding and edge trimming processes, in accordance with a preferred embodiment of the present invention. As shown, following the completion of the wafer stacking and bonding steps, the structure is subjected to backside grinding and edge trimming to remove the unnecessary semiconductor substrate portion of the topmost wafer, i.e., wafer W3. These processes reduce wafer W3 to retain only its device layer and associated metal interconnect layers. As illustrated in the figure, after thinning, wafer W3 still retains the previously described TSVs T3, particularly those located within the edge region WE. These TSVs T3 provide critical mechanical reinforcement during the backside grinding and edge trimming operations, effectively preventing issues such as edge chipping - commonly observed in conventional wafer dicing processes. This structural advantage highlights one of the key benefits and functionalities of the structure of the present invention.

It should be noted that, although the TSVs T3 in the aforementioned embodiment are implemented using the via-middle process, the scope of the present invention is not limited thereto. Other TSV fabrication processes, including the via-first process and the via-last process, may also be employed without departing from the spirit and scope of the invention. Furthermore, in the aforementioned embodiment, the wafers W1 to W4 may be bonded together through any suitable type of interconnects, including through-silicon vias (TSVs), hybrid bonding vertical interconnects (HBVs), or metal bumps. The present invention is not limited to the specific examples provided herein.

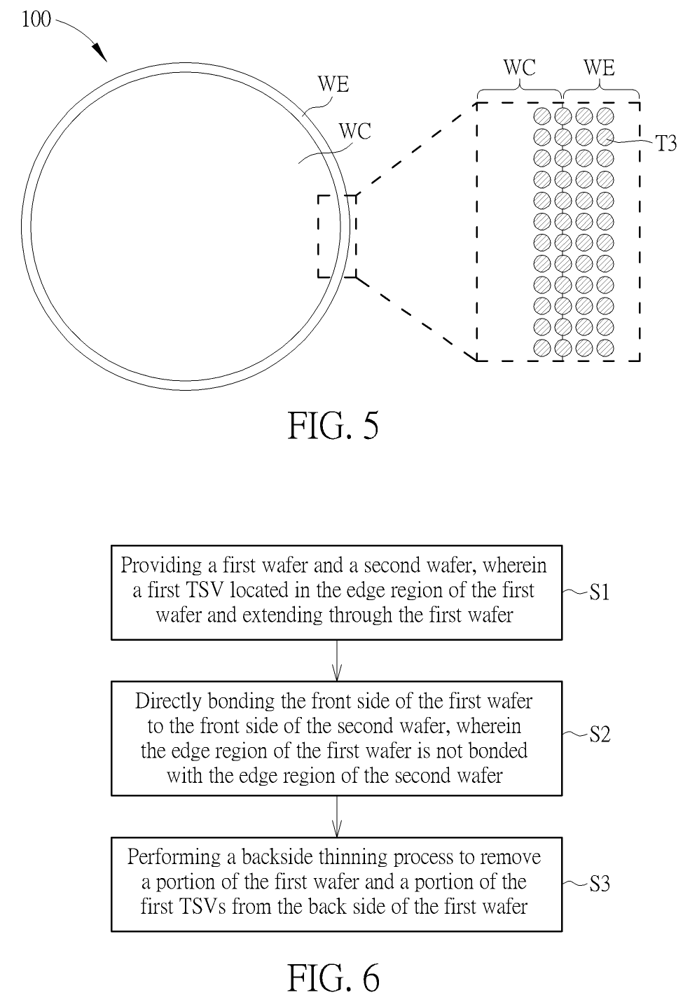

Based on the wafer bonding structure disclosed in the foregoing embodiments, the present invention further provides a wafer bonding method. Please refer to FIG. 6, which illustrates a process flow of the wafer bonding method in accordance with a preferred embodiment of the present invention. In Step S1 (see also FIG. 3), a wafer W1 and a wafer W3 are provided. Each of wafers W1 and W3 includes a front side and a back side, as well as an outermost edge region WE. In wafer W3, a TSV T3 is formed within the edge region WE and is exposed from the back side of wafer W3. In Step S2 (also referring to FIG. 3), the front side of wafer W1 is directly bonded to the front side of wafer W3. It should be noted that the edge region of wafer W1 remains unbonded with respect to the corresponding edge region WE of wafer W3. In Step S3 (see also FIG. 4), a backside thinning process is performed on wafer W3 to remove a portion of its substrate from the back side, including part of the TSV T3. This thinning exposes the device layer and allows the TSV T3 to remain partially embedded in the edge region WE, thereby providing structural support during subsequent processing.

Referring again to FIG. 3, in certain embodiments, the provided wafers W1 and W3 each include a device layer and an associated BEOL interconnect layer thereon. The front side of each wafer corresponds to the surface where the BEOL metal interconnect layer is formed, while the back side corresponds to the side of the semiconductor substrate beneath the device layer. After wafers W1 and W3 are bonded, their respective BEOL metal interconnect layers collectively form a hybrid bonding layer HB2, in which hybrid bonding vias HBVs directly and precisely align and bond with each other to establish electrical and mechanical interconnection between the wafers.

Further referring to FIG. 3, in other embodiments, wafer W1 forms part of a first wafer pair, composed of wafers W1 and W2, and wafer W3 forms part of a second wafer pair, composed of wafers W3 and W4. The first wafer pair and the second wafer pair are bonded together via direct alignment and interconnection of TSVs - specifically, TSV T1 on wafer W2 and TSV T2 on wafer W4.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wafer bonding structure, comprising:
a first wafer having a first front side and a first back side;
a second wafer having a second front side and a second back side, wherein the second front side of the second wafer is bonded to the first front side of the first wafer, and the first wafer and the second wafer have an outermost edge region, and the edge region of the first wafer is not bonded to the edge region of the second wafer; and
a first TSV located in the edge region of the first wafer and extending through the first wafer to expose at the first back side of the first wafer.

2. The wafer bonding structure of claim 1, wherein the first wafer further comprises a first device layer and a first BEOL metal interconnect layer, with the first front side being a side of the first BEOL metal interconnect layer, and the first back side being a side of the first device layer, and the second wafer further comprises a second device layer and a second BEOL metal interconnect layer, with the second front side being a side of the second BEOL metal interconnect layer, and the second back side being a side of the second device layer.

3. The wafer bonding structure of claim 2, wherein the first BEOL metal interconnect layer comprises first hybrid bonding vias, the second BEOL metal interconnect layer comprises second hybrid bonding vias, and the first wafer and the second wafer are bonded together through direct alignment and interconnection of the first hybrid bonding vias and the second hybrid bonding vias.

4. The wafer bonding structure of claim 3, wherein the first hybrid bonding vias do not locate in the edge region of the first wafer, and the second hybrid bonding vias do not locate in the edge region of the second wafer.

5. The wafer bonding structure of claim 3, wherein the first BEOL metal interconnect layer in the edge region of the first wafer and the second BEOL metal interconnect layer in the edge region of the second wafer are separated by a gap and are not electrically connected.

6. The wafer bonding structure of claim 3, wherein a bonding region of the first wafer is defined as a region excluding the edge region of the first wafer, a number of the first TSVs are located within the bonding region and are electrically connected with the first hybrid bonding vias in the first BEOL metal interconnect layer.

7. The wafer bonding structure of claim 1, wherein portions of inter-metal dielectric layers in the first BEOL metal interconnect layer and the second BEOL metal interconnect layer in the edge region are missing.

8. The wafer bonding structure of claim 1, wherein the first wafer and a third wafer form a first wafer pair, the second wafer and a fourth wafer form a second wafer pair, and the first wafer pair is bonded to the second wafer pair through direct alignment and interconnection of second TSVs on the third wafer and corresponding third TSVs on the fourth wafer.

9. A wafer bonding method, comprising:
providing a first wafer and a second wafer, wherein the first wafer has a first front side and a first back side, and the second wafer has a second front side and a second back side, and the first wafer and the second wafer have an outermost edge region, a first TSV located in the edge region of the first wafer and extending through the first wafer to expose at the first back side of the first wafer;
directly bonding the first front side of the first wafer to the second front side of the second wafer, wherein the edge region of the first wafer is not bonded to the edge region of the second wafer; and
performing a backside thinning process to remove a portion of the first wafer and a portion of the first TSVs from the first back side of the first wafer.

10. The wafer bonding method of claim 9, wherein the first wafer further comprises a first device layer and a first BEOL metal interconnect layer, with the first front side being a side of the first BEOL metal interconnect layer, and the first back side being a side of the first device layer, and the second wafer further comprises a second device layer and a second BEOL metal interconnect layer, with the second front side being a side of the second BEOL metal interconnect layer, and the second back side being a side of the second device layer.

11. The wafer bonding method of claim 10, wherein providing the first wafer further comprises:
forming the first device layer on the first wafer;
forming the first TSVs through the first wafer to expose from the first device layer after forming the first device layer; and
forming the first BEOL metal interconnect layer over the first device layer after forming the first TSVs.

12. The wafer bonding method of claim 10, wherein the first BEOL metal interconnect layer comprises first hybrid bonding vias, the second BEOL metal interconnect layer comprises second hybrid bonding vias, and directly bonding the first front side of the first wafer to the second front side of the second wafer comprises direct aligning and interconnecting the first hybrid bonding vias to the corresponding second hybrid bonding vias.

13. The wafer bonding method of claim 12, wherein the first hybrid bonding vias do not locate in the edge region of the first wafer, and the second hybrid bonding vias do not locate in the edge region of the second wafer.

14. The wafer bonding method of claim 12, wherein a bonding region of the first wafer is defined as a region excluding the edge region of the first wafer, a number of the first TSVs are located within the bonding region and are electrically connected with the first hybrid bonding vias in the first BEOL metal interconnect layer.

15. The wafer bonding method of claim 10, wherein the first BEOL metal interconnect layer in the edge region of the first wafer and the second BEOL metal interconnect layer in the edge region of the second wafer are separated by a gap and are not electrically connected.

16. The wafer bonding method of claim 10, wherein portions of inter-metal dielectric layers in the first BEOL metal interconnect layer and the second BEOL metal interconnect layer in the edge region are missing.

17. The wafer bonding method of claim 9, wherein the first wafer and a third wafer form a first wafer pair, the second wafer and a fourth wafer form a second wafer pair, and the first wafer pair is bonded to the second wafer pair through direct alignment and interconnection of second TSVs on the third wafer and corresponding third TSVs on the fourth wafer.
